(19) United States
(12) Patent Application Publication
(10) Pub. No.: US 2021/0233775 A1
(43) Pub. Date: Jul. 29, 2021

(54) HIGH-THROUGHPUT DRY ETCHING OF SILICON OXIDE AND SILICON NITRIDE MATERIALS BY IN-SITU AUTOCATALYST FORMATION

(71) Applicant: Tokyo Electron Limited, Tokyo (JP)

(72) Inventors: Du Zhang, Albany, NY (US); Manabu Iwata, Miyagi (JP); Yu-Hao Tsai, Albany, NY (US); Takahiro Yokoyama, Miyagi (JP); Yanxiang Shi, Albany, NY (US); Yoshihide Kihara, Miyagi (JP); Wataru Sakamoto, Miyagi (JP); Mingmei Wang, Albany, NY (US)

(21) Appl. No.: 17/149,067

(22) Filed: Jan. 14, 2021

Related U.S. Application Data
(60) Provisional application No. 62/965,611, filed on Jan. 24, 2020.

(51) Int. Cl. H01L 21/311

(52) U.S. Cl. CPC H01L 21/31116

(57) ABSTRACT

A method of high-throughput dry etching of silicon oxide and silicon nitride materials by in-situ autocatalyst formation. The method includes providing a substrate having a film thereon in a process chamber, the film containing silicon oxide, silicon nitride, or both silicon oxide and silicon nitride, introducing an etching gas containing fluorine and hydrogen, and setting a gas pressure in the process chamber that is between about 1 mTorr and about 300 mTorr, and a substrate temperature that is below about −30° C. The method further includes plasma-exciting the etching gas, and exposing the film to the plasma-excited etching gas, where the film is continuously etched during the exposing.

### CROSS-REFERENCE TO RELATED APPLICATIONS

This application claims priority to U.S. Provisional Patent Application No. 62/965,611, entitled, “High-throughput Dry Etching of Silicon Oxide and Silicon Nitride Materials by In-situ Autocatalyst Formation,” filed Jan. 24, 2020; the disclosure of which is expressly incorporated herein, in its entirety, by reference.

### FIELD OF INVENTION

The present invention relates to the field of semiconductor manufacturing and semiconductor devices, and more particularly, to a method of plasma etching silicon oxide and silicon nitride materials in semiconductor manufacturing.

### BACKGROUND OF THE INVENTION

Manufacturing of advanced semiconductor devices requires high-throughput dry etching of silicon oxide and silicon nitride materials.

### SUMMARY OF THE INVENTION

A method of plasma etching of silicon oxide and silicon nitride materials in semiconductor manufacturing is disclosed in several embodiments.

According to one embodiment, the method includes providing a substrate having a film thereon in a process chamber, the film containing silicon oxide, silicon nitride, or both silicon oxide or silicon nitride, introducing an etching gas containing fluorine and hydrogen, and setting a gas pressure in the process chamber that is between about 1 mTorr and about 300 mTorr and a substrate temperature that is below about −30° C. (i.e., more negative than −30° C.). The method further includes plasma-exciting the etching gas, and exposing the film to the plasma-excited etching gas, where the film is continuously etched during the exposing.

### DETAILED DESCRIPTION OF THE DRAWINGS

In the accompanying drawings:

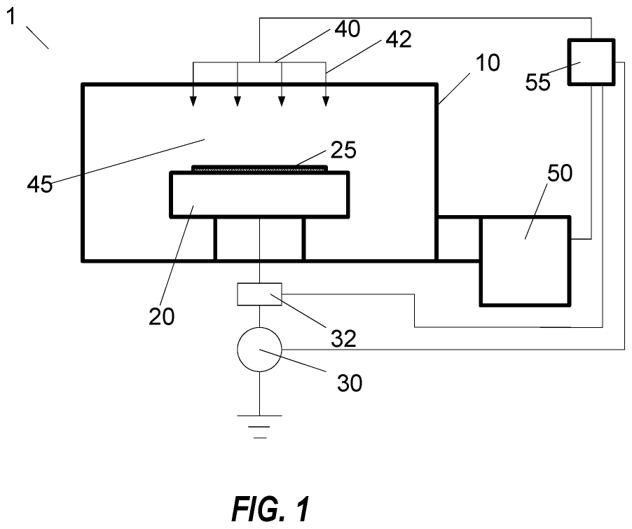

FIG. 1 schematically shows a plasma processing system according to one embodiment of the invention;

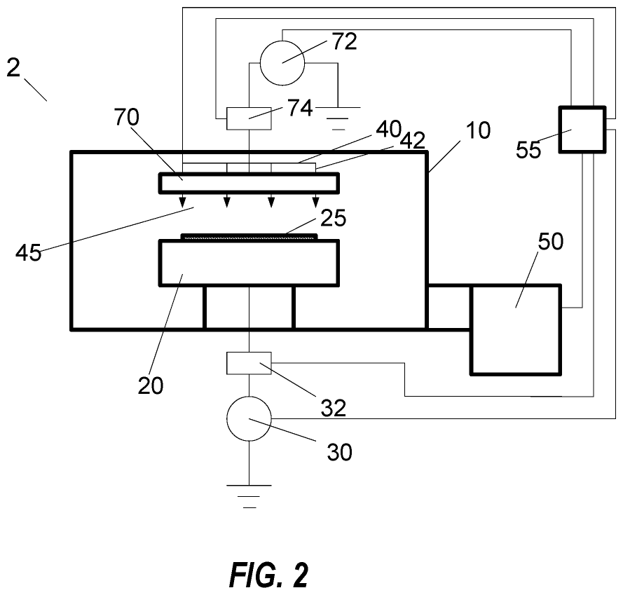

FIG. 2 schematically shows a plasma processing system according to another embodiment of the invention;

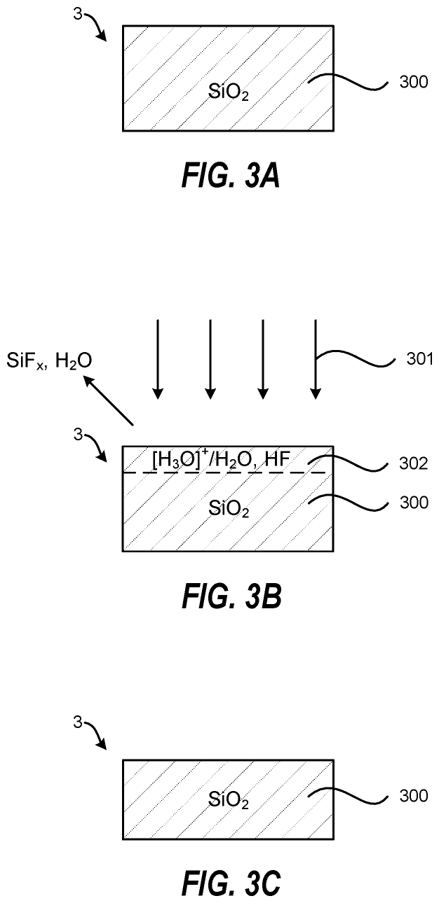

FIGS. 3A-3C schematically show through cross-sectional views a method of dry etching a silicon oxide film by in-situ autocatalyst formation according to an embodiment of the invention;

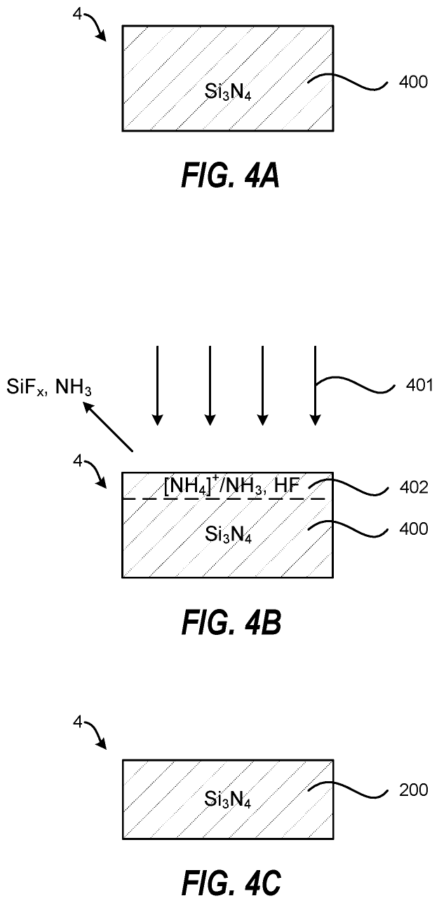

FIGS. 4A-4C schematically show through cross-sectional views a method of dry etching a silicon nitride film by in-situ autocatalyst formation according to an embodiment of the invention; and

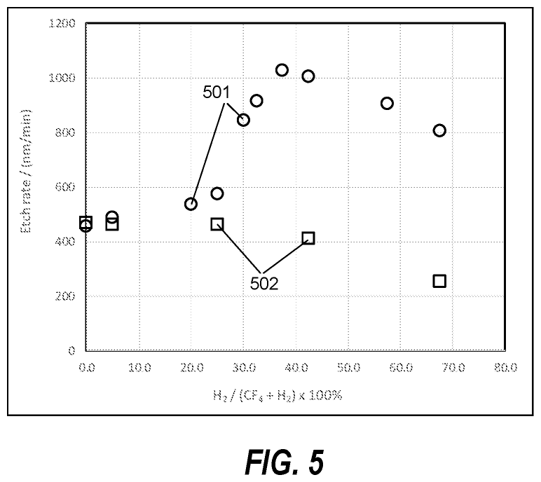

FIG. 5 shows SiO₂ etch rate as a function of etching gas composition and substrate temperature according to an embodiment of the invention.

### DETAILED DESCRIPTION OF SEVERAL EMBODIMENTS

A method of high-throughput dry etching of silicon oxide and silicon nitride materials by in-situ autocatalyst formation is described. For example, the method may be used for etching high-aspect-ratio contact holes (HARC) in dynamic random access memory (DRAM) devices and etching 3D-NAND flash memory devices.

According to embodiments of the invention, silicon oxide and silicon nitride films on a substrate are etched using a plasma-excited etching gas that contains fluorine and hydrogen, where the films are continuously etched during the gas exposure. A gas pressure in the process chamber is set between about 1 mTorr and about 300 mTorr. Further, a temperature of the substrate is maintained at below about −30° C., below about −50° C., or below about −70° C. Further, the substrate temperature may be maintained between below about −30° C. and about −120° C., between below about −30° C. and about −100° C., between below about −30° C. and about −70° C., between about −50° C. and about −70° C., or between about −50° C. and about −100° C.

Conventional substrate temperatures for gas phase etching processes are performed at approximately room temperature and this results in surface scavenging of fluorine species by hydrogen species. However, the low substrate temperatures in embodiments of the invention increase the concentration of [H₃O]⁺/H₂O surface species on silicon oxide films and concentration of NH₄⁺/NH₃ surface species on silicon nitride films by reducing the desorption of these surface species from the substrate. This in turn increases the concentration of HF surface species that are effective in etching of the silicon oxide and silicon nitride films.

The silicon oxide materials can have Si and O as the major constituents, and can, for example, include SiO₂, non-stoichiometric silicon oxides that can have a wide range of Si and O compositions (e.g., SiOₓ, where x<2)), and nitridated silicon oxides. SiO₂ is the most thermodynamically stable of the silicon oxide materials and hence the most commercially important. Similarly, the silicon nitride materials can have Si and N as the major constituents, and can, for example, include Si₃N₄, non-stoichiometric silicon nitrides that can have a wide range of Si and N compositions, and oxidized silicon nitrides. Si₃N₄ is the most thermodynamically stable of the silicon nitrides and hence the most commercially important of the silicon nitrides.

FIG. 1 schematically shows a plasma processing system according to one embodiment of the invention. The plasma processing system 1 depicted in FIG. 1 includes a process chamber 10, a substrate holder 20, upon which a substrate 25 to be processed is affixed, a gas injection system 40, and a vacuum pumping system 50. The process chamber 10 is configured to facilitate the generation of plasma in a processing region 45 adjacent a surface of the substrate 25, where plasma is formed via collisions between heated electrons and an ionizable gas. An ionizable gas or mixture of gases is introduced via the gas injection system 40 and the process pressure is adjusted. For example, a gate valve (not shown) may be used to throttle the evacuation of the process chamber 10 by the vacuum pumping system 50.

The substrate 25 is transferred into and out of chamber 10 through a slot valve (not shown) and chamber feed-through (not shown) via robotic substrate transfer system where it is received by substrate lift pins (not shown) housed within substrate holder 20 and mechanically translated by devices housed therein. Once the substrate 25 is received from the substrate transfer system, it is lowered to an upper surface of the substrate holder 20.

In an alternate embodiment, the substrate 25 is affixed to the substrate holder 20 via an electrostatic clamp (not shown). Furthermore, the substrate holder 20 further includes a cooling system with a re-circulating coolant flow that receives heat from the substrate holder 20 and the substrate 25 and transfers heat to a heat exchanger system (not shown), or when heating, transfers heat from the heat exchanger system. Moreover, gas may be delivered to the back-side of the substrate 25 to improve the gas-gap thermal conductance between the substrate 25 and the substrate holder 20. Such a system is utilized when temperature control of the substrate is required at elevated or reduced temperatures. For example, temperature control of the substrate 25 may be useful at temperatures in excess of the steady-state temperature achieved due to a balance of the heat flux delivered to the substrate 25 from the plasma and the heat flux removed from substrate 25 by conduction to the substrate holder 20. In other embodiments, heating elements, such as resistive heating elements, or thermo-electric heaters/coolers may be included. According to one embodiment, the substrate holder 20 may be configured for maintaining the substrate 1 at a substrate temperature below about −30° C., below about −50° C., or below about −70° C. Further, the substrate temperature may be between below about −30° C. and about −120° C., between below about −30° C. and about −100° C., between below about −30° C. and about −70° C., between about −50° C. and about −70° C., or between about −50° C. and about −100° C.

In one embodiment, shown in FIG. 1, the substrate holder 20 further serves as an electrode through which radio frequency (RF) power is coupled to plasma in the processing region 45. For example, the substrate holder 20 is electrically biased at a RF voltage via the transmission of RF power from an RF generator 30 through an impedance match network 32 to the substrate holder 20. The RF bias serves to heat electrons and, thereby, form and maintain plasma in the processing region 45. In this configuration, the system operates as a reactive ion etching (RIE) reactor, where the chamber wall and the gas injection system 40 serve as ground surfaces. A frequency for the RF bias can, for example range from about 400 KHz to about 100 MHz, or from about 1 MHz to about 100 MHz, and can be 13.56 MHz.

In another embodiment, RF power is applied to the substrate holder electrode at multiple frequencies. In some examples, the frequency for the RF bias can be 400 KHz, or both 400 KHz and 40 MHz. Furthermore, the impedance match network 32 serves to maximize the transfer of RF power to plasma in process chamber 10 by minimizing the reflected power. Match network topologies (e.g. L-type, π-type, T-type, etc.) and automatic control methods are known in the art.

With continuing reference to FIG. 1, a process gas 42 (e.g., an etching gas) is introduced to the processing region 45 through the gas injection system 40. The gas injection system 40 can include a showerhead, wherein the process gas 42 is supplied from a gas delivery system (not shown) to the processing region 45 through a gas injection plenum (not shown), a series of baffle plates (not shown) and a multi-orifice showerhead gas injection plate (not shown). Vacuum pump system 50 preferably includes a turbo-molecular vacuum pump (TMP) capable of a pumping speed up to 5000 liters per second (and greater) and a gate valve (not shown) for throttling the gas exhaust and controlling the chamber gas pressure.

A computer 55 includes a microprocessor, a memory, and a digital I/O port capable of generating control voltages sufficient to communicate and activate inputs to the plasma processing system 1 as well as monitor outputs from the plasma processing system 1. Moreover, the computer 55 is coupled to and exchanges information with the RF generator 30, the impedance match network 32, the gas injection system 40 and the vacuum pump system 50. A program stored in the memory is utilized to activate the inputs to the aforementioned components of a plasma processing system 1 according to a stored process recipe.

In another embodiment, shown in FIG. 2, the plasma processing system 2 further includes an upper plate electrode 70 to which RF power is coupled from an RF generator 72 through an impedance match network 74. A typical frequency for the application of RF power to the upper electrode ranges from 10 MHz to 200 MHz and is preferably 60 MHz. Additionally, a typical frequency for the application of power to the lower electrode ranges from 0.1 MHz to 30 MHz and is preferably 2 MHz. Moreover, the computer 55 is coupled to the RF generator 72 and the impedance match network 74 in order to control the application of RF power to the upper electrode 70.

In other embodiments, the plasma etching may be performed in inductively coupled plasma (ICP) systems, remote plasma systems that generate plasma excited species upstream from the substrate, or electron cyclotron resonance (ECR) systems.

FIGS. 3A-3C schematically show through cross-sectional views a method of dry etching a silicon oxide film by in-situ autocatalyst formation according to an embodiment of the invention. FIG. 3A schematically shows a substrate 3 containing a SiO₂ film 300 to be etched in a dry etching process. The method includes providing the substrate 3 into a process chamber, and positioning the substrate 3 on a substrate holder. The substrate holder may be configured for maintaining the substrate 1 at a substrate temperature below about −30° C., below about −50° C., or below about −70° C. Further, the substrate temperature may be between below about −30° C. and about −120° C., between below about −30° C. and about −100° C., between below about −30° C. and about −70° C., between about −50° C. and about −70° C., or between about −50° C. and about −100° C.

The method further includes introducing into the process chamber an etching gas containing fluorine and hydrogen. According to one embodiment, the etching gas contains HF, CH₂F₂, CHF₃, CH₃F, or a combination thereof. According to one embodiment, the etching gas contains H₂ and CF₄. According to one embodiment, the etching gas contains a first gas containing fluorine and a second gas containing hydrogen, where the second gas is different from the first gas. According to one embodiment, the first gas may be selected from the group consisting of HF, CF₄, CH₂F₂, CHF₃, SF₆, C₂F₆, C₄F₈, C₃F₈, C₄F₆, ClF₃, F₂, XeF₂, and NF₃. According to one embodiment, the second gas may be selected from the group consisting of H₂, CH₄, CH₂F₂, CHF₃, CH₃F, C₂H₆, H₂S, HF, HCl, HBr, and HI. The etching gas may further include Ar, He, Xe, Kr, Ne, N₂, O₂, or a combination thereof. Once the gas flow of the etching gas has been initiated, the method further includes setting a gas pressure in the plasma process chamber that is between about 1 mTorr and about 300 mTorr, between about 1 mTorr and about 50 mTorr, between about 50 mTorr and about 100 mTorr, or between about 100 mTorr and about 300 mTorr. The gas pressure in the process chamber may be set by selecting the gas flow of the etching gas and using a gate valve for throttling the exhaust gas flow.

Thereafter, the etching gas is plasma-excited and the substrate 3 is exposed to the plasma-excited etching gas. During the gas exposure, the SiO₂ film 300 is continuously etched. As schematically shown in FIG. 3B, the exposure to the plasma-excited etching gas 301 forms an adsorption layer 302 with an etch front complex containing [H₃O]⁺/H₂O and HF surface species that accelerate the etching of the SiO₂ film 300. The formation of this complex containing [H₃O]⁺/H₂O and HF results from the suppressed desorption of SiO₂ etch by-products (e.g., H₂O) at low temperatures. The [H₃O]⁺/H₂O and HF surface species in the adsorption layer 302 are etch by-products that are formed by chemical reactions of the plasma-excited etching gas with the SiO₂ film 300. The formation of the [H₃O]⁺/H₂O surface species is thought to increase the adsorption energy of the HF surface species, which lowers the volatility of the HF surface species and therefore provides high HF surface coverage. The [H₃O]⁺/H₂O surface species also serve as proton mediators for the HF surface species to react with the SiO₂ film 300 via a Bronsted acid-base mechanism. This results in a strong autocatalytic effect due to the high surface fluorine reactant density and low activation energy and provides high etch rate of the SiO₂ film 300. The dry etching of the SiO₂ film forms volatile by-products that include SiFₓ(g) and H₂O(g). The volatile by-products are exhausted from the process chamber by a vacuum pumping system. FIG. 3C schematically shows the etched SiO₂ film 300.

FIGS. 4A-4C schematically show through cross-sectional views a method of dry etching a silicon nitride film by in-situ autocatalyst formation according to an embodiment of the invention. FIG. 4A schematically shows a substrate 4 containing a Si₃N₄ film 400 to be etched in a dry etching process. The method includes providing the substrate 4 into a process chamber, and positioning the substrate 4 on a substrate holder. The substrate holder may be configured for maintaining the substrate 1 at a substrate temperature below about −30° C., below about −50° C., or below about −70° C. Further, the substrate temperature may be between below about −30° C. and about −120° C., between below about −30° C. and about −100° C., between below about −30° C. and about −70° C., between about −50° C. and about −70° C., or between about −50° C. and about −100° C.

The method further includes introducing into the process chamber an etching gas containing fluorine and hydrogen. According to one embodiment, the etching gas contains HF, CH₂F₂, CHF₃, CH₃F, or a combination thereof. According to one embodiment, the etching gas contains H₂ and CF₄. According to one embodiment, the etching gas contains a first gas containing fluorine and a second gas containing hydrogen, where the second gas is different from the first gas. According to one embodiment, the first gas may be selected from the group consisting of HF, CF₄, CH₂F₂, CHF₃, SF₆, C₂F₆, C₄F₈, C₃F₈, C₄F₆, ClF₃, F₂, XeF₂, and NF₃. According to one embodiment, the second gas may be selected from the group consisting of H₂, CH₄, CH₂F₂, CHF₃, CH₃F, C₂H₆, H₂S, HF, HCl, HBr, and HI. The etching gas may further include Ar, He, Xe, Kr, Ne, N₂, O₂, or a combination thereof. Once the gas flow of the etching gas has been initiated, the method further includes setting a gas pressure in the plasma process chamber that is between about 1 mTorr and about 300 mTorr, between about 1 mTorr and about 50 mTorr, between about 50 mTorr and about 100 mTorr, or between about 100 mTorr and about 300 mTorr. The gas pressure in the process chamber may be set by selecting the gas flow of the etching gas and using a gate valve for throttling the exhaust gas flow.

Thereafter, the etching gas is plasma-excited and the substrate 4 is exposed to the plasma-excited etching gas. During the gas exposure, the Si₃N₄ film 400 is continuously etched. As schematically shown in FIG. 4B, the exposure to the plasma-excited etching gas 401 forms an adsorption layer 402 with an etch front complex containing [NH₄]⁺/NH₃ and HF surface species that accelerate the etching of the Si₃N₄ film 400. The formation of this complex containing [NH₄]⁺/NH₃ and HF results from the suppressed desorption of Si₃N₄ etch by-products (e.g., NH₃) at low temperatures. The [NH₄]⁺/NH₃ and HF surface species in the adsorption layer 402 are etch by-products that are formed by chemical reactions of the plasma-excited etching gas with the Si₃N₄ film 400. The formation of the [NH₄]⁺/NH₃ surface species is thought to increase the adsorption energy of the HF surface species, which lowers the volatility of the HF surface species and therefore provides high HF surface coverage. The [NH₄]⁺/NH₃ surface species also serve as a proton mediator for the HF surface species to react with the Si₃N₄ film 400 via a Bronsted acid-base mechanism. This results in a strong autocatalytic effect due to the high surface fluorine reactant density and provides high etch rate of the Si₃N₄ film 400. The dry etching of the Si₃N₄ film forms volatile by-products that include SiFₓ(g) and NH₃(g). The volatile by-products are exhausted from the process chamber by a vacuum pumping system. FIG. 4C schematically shows the etched Si₃N₄ film 400.

FIG. 5 shows SiO₂ etch rate as a function of etching gas composition and substrate temperature according to an embodiment of the invention. SiO₂ films were continuously etched for 30 seconds using a plasma-excited etching gas containing different amounts of CF₄ and Hz. A total gas flow rate of the etching gas was 400 sccm, and the substrate temperature was maintained at a temperature of about −60° C. (open circles 501) or about 25° C. (open squares 502). The etching gas was plasma-excited using a plasma processing system schematically shown in FIG. 2, where a power of 2500 W at 40 MHz was applied to the upper plate electrode 70 and a power of 1000 W at 400 KHz was applied to the substrate holder 20. The experimental results showed that the SiO₂ etch rate was about 2.5 times greater at a substrate temperature of about −60° C. than at about 25° C. for a H₂/(CF₄+Hz)×100% ratio of about 40%. Further, the SiO₂ etch rate was greater at a substrate temperature of about −60° C. than at about 25° C. for a H₂/(CF₄+Hz)×100% ratio greater than about 20%. The unexpected increase in the SiO₂ etch rate at about −60° C. compared to the SiO₂ etch rate at about 25° C. is thought to be due to the strong autocatalytic effect described above and includes high surface fluorine reactant density and low activation energy on the SiO₂ film at −60° C.

A plurality of embodiments for a method of plasma etching silicon oxide and silicon nitride materials in semiconductor manufacturing have been described. The foregoing description of the embodiments of the invention has been presented for the purposes of illustration and description. It is not intended to be exhaustive or to limit the invention to the precise forms disclosed. This description and the claims following include terms that are used for descriptive purposes only and are not to be construed as limiting. Persons skilled in the relevant art can appreciate that many modifications and variations are possible in light of the above teaching. It is therefore intended that the scope of the invention be limited not by this detailed description, but rather by the claims appended hereto.

What is claimed is:

1. A substrate etching method, comprising:
providing a substrate having a film thereon in a process chamber, the film containing silicon oxide, silicon nitride, or both silicon oxide and silicon nitride;
introducing an etching gas containing fluorine and hydrogen;
setting a gas pressure in the process chamber that is between about 1 mTorr and about 300 mTorr, and a substrate temperature that is below about −30° C.;
plasma-exciting the etching gas; and
exposing the film to the plasma-excited etching gas, wherein the film is continuously etched during the exposing.

2. The method of claim 1, wherein the substrate temperature is below about −50° C.

3. The method of claim 1, wherein the substrate temperature is below about −70° C.

4. The method of claim 1, wherein the substrate temperature is between below about −30° C. and about −120° C.

5. The method of claim 1, wherein the etching gas contains a first gas and a second gas that is different from the first gas, wherein the first gas is selected from the group consisting of HF, CF₄, CHF₃, CH₂F₂, SF₆, C₂F₆, C₄F₈, C₃F₈, C₄F₆, ClF₃, F₂, XeF₂, and NF₃, and wherein the second gas is selected from the group consisting of H₂, CH₄, CH₂F₂, CHF₃, CH₃F, C₂H₆, H₂S, HF, HCl, HBr, and HI.

6. The method of claim 1, wherein the etching gas contains HF, CHF₃, CH₂F₂, CH₃F, or a combination thereof.

7. The method of claim 1, wherein the etching gas contains H₂ and CF₄.

8. The method of claim 1, wherein the silicon oxide film includes SiO₂, a non-stoichiometric silicon oxide, or a nitridated silicon oxide, and wherein the silicon nitride film includes Si₃N₄, a non-stoichiometric silicon nitride, or an oxidized silicon nitride.

9. A substrate etching method, comprising:
providing a substrate having a silicon oxide film thereon in a process chamber;
introducing an etching gas containing fluorine and hydrogen;
setting a gas pressure in the process chamber that is between about 1 mTorr and about 300 mTorr, and a substrate temperature that is below about −30° C.;
plasma-exciting the etching gas; and
exposing the silicon oxide film to the plasma-excited etching gas, wherein the silicon oxide film is continuously etched during the exposing.

10. The method of claim 9, wherein the substrate temperature is below about −50° C.

11. The method of claim 9, wherein the substrate temperature is below about −70° C.

12. The method of claim 9, wherein the etching gas contains a first gas and a second gas that is different from the first gas, wherein the first gas is selected from the group consisting of HF, CF₄, CHF₃, CH₂F₂, SF₆, C₂F₆, C₄F₈, C₃F₈, C₄F₆, ClF₃, F₂, XeF₂, and NF₃, and wherein the second gas is selected from the group consisting of H₂, CH₄, CH₂F₂, CHF₃, CH₃F, C₂H₆, H₂S, HF, HCl, HBr, and HI.

13. The method of claim 9, wherein the etching gas contains HF, CHF₃, CH₂F₂, CH₃F, or a combination thereof.

14. The method of claim 9, wherein the etching gas contains H₂ and CF₄.

15. A substrate etching method, comprising:
providing a substrate having a silicon nitride film thereon in a process chamber;
introducing an etching gas containing fluorine and hydrogen;
setting a gas pressure in the process chamber that is between about 1 mTorr and about 300 mTorr, and a substrate temperature that is below about −30° C.;
plasma-exciting the etching gas; and
exposing the silicon nitride film to the plasma-excited etching gas, wherein the silicon nitride film is continuously etched during the exposing.

16. The method of claim 15, wherein the substrate temperature is below about −50° C.

17. The method of claim 15, wherein the substrate temperature is below about −70° C.

18. The method of claim 15, wherein the etching gas contains a first gas and a second gas that is different from the first gas, wherein the first gas is selected from the group consisting of HF, CF₄, CHF₃, CH₂F₂, SF₆, C₂F₆, C₄F₈, C₃F₈, C₄F₆, ClF₃, F₂, XeF₂, and NF₃, and wherein the second gas is selected from the group consisting of H₂, CH₄, CH₂F₂, CHF₃, CH₃F, C₂H₆, H₂S, HF, HCl, HBr, and HI.

19. The method of claim 15, wherein the etching gas contains HF, CH₂F₂, CHF₃, CH₃F, or a combination thereof.

20. The method of claim 15, wherein the etching gas contains H₂ and CF₄.
